(19) United States
(12) Patent Application Publication
(10) Pub. No.: US 2025/0203925 A1
(43) Pub. Date: Jun. 19, 2025

(54) TRANSISTOR DEVICE AND METHOD

(71) Applicant: Infineon Technologies Austria AG, Villach (AT)

(72) Inventors: Alessandro Ferrara, Villach (AT); Stefan Tegen, Dresden (DE)

(21) Appl. No.: 18/971,368

(22) Filed: Dec. 6, 2024

(30) Foreign Application Priority Data
Dec. 13, 2023 (DE) 102023212608.7

(51) Int. Cl. H10D 30/66; H10D 30/01; H10D 64/23

(52) U.S. Cl. CPC H10D 30/668; H10D 30/0297; H10D 64/252

(57) ABSTRACT

In an embodiment, a transistor device includes a semiconductor substrate having at least one transistor cell. The transistor cell includes an elongate trench and an elongate mesa. The elongate trench is arranged in the first major surface of the semiconductor substrate and includes an elongate gate electrode electrically separated from the semiconductor substrate by a gate dielectric. A first insulating layer arranged on the first major surface covers the elongate trench. An elongate contact connection strip arranged on the first insulating layer extends above and parallel to the elongate trench. The elongate contact connection strip is electrically connected to the elongate gate electrode in the elongate trench by at least one first contact that extends through the first insulating layer.

### BACKGROUND

Transistor devices used in power electronic applications may be fabricated with silicon (Si) semiconductor materials. Common transistor devices for power applications include Si CoolMOS®, Si Power MOSFETs, and Si Insulated Gate Bipolar Transistors (IGBTs).

Generally, an n-channel trench-gate power MOSFET includes a semiconductor substrate which may comprise a n-type base substrate on which an n-type epitaxial layer is formed. The base substrate provides the drain of the MOSFET. A p-type body region extends into the epitaxial layer and a n-type source region is formed on or in the body region. Trench gate MOSFETs include a plurality of trenches which extend through the body region and into the epitaxial layer. Each trench is lined by a gate dielectric layer that is formed on the sidewalls and bottom of each trench. A gate electrode is formed in each of the trenches and a dielectric layer covers the trenches and also partially extends over the source regions. The gate electrode is typically formed of polysilicon. A top-side metal layer electrically contacts the source regions and the body regions. Some designs of trench power MOSFETS further include a field plate located in the trench underneath the gate electrode.

Improvements in transistor performance can be achieved by reducing gate resistance in such trench gate transistor devices. For example, WO 2009/079473 A1 describes a transistor device with a metallic gate electrode in a gate trench with the aim of reducing the gate resistance. Further improvements to the performance of trench gate transistor devices are desirable.

### SUMMARY

In an exemplary embodiment, a transistor device is provided that comprises a semiconductor substrate comprising at least one transistor cell. The transistor cell comprises an elongate trench and an elongate mesa; the elongate trench being arranged in a first major surface of the semiconductor substrate and comprising an elongate gate electrode that is electrically separated from the semiconductor substrate by a gate dielectric. The transistor device further comprises a first insulating layer which is arranged on the first major surface and covers the elongate trench and an elongate contact connection strip arranged on the first insulating layer and extending above and parallel to the elongate trench. The elongate contact connection strip is electrically connected to the elongate gate electrode in the elongate trench by at least one first contact that extends through the first insulating layer.

In an exemplary embodiment, a method comprises forming a first insulating layer on a first major surface of a semiconductor substrate comprising at least one transistor cell, the transistor cell comprising an elongate trench and an elongate mesa, wherein the elongate trench is arranged in the first major surface of the semiconductor substrate and comprises an elongate gate electrode that is electrically separated from the semiconductor substrate by a gate dielectric, wherein the first insulating layer covers the elongate trench. The method further comprises forming at least one first contact in the first insulating layer that is connected to the elongate gate electrode in the elongate trench, forming an elongate contact connection strip on the first insulating layer and on the at least one first contact, wherein the elongate contact connection strip extends vertically above and parallel to the gate trench, forming a second insulating layer on the elongate contact connection strip, forming a source metal layer on the second insulating layer and electrically connecting the source metal layer to the mesa. The source metal layer extends over and is electrically insulated from the elongate contact connection strip by the second insulating layer.

Those skilled in the art will recognize additional features and advantages upon reading the following detailed description, and upon viewing the accompanying drawings.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Exemplary embodiments are depicted in the drawings and are detailed in the description which follows.

FIGS. 1A to 1J illustrate various views of a transistor device according to various embodiments.

FIG. 2 illustrates a graph of gate resistance and stress simulated for transistor devices comprising with differing contact duty cycles (gate contact collective lengths).

FIGS. 3A to 3H illustrate a method for fabricating a transistor device.

FIG. 4 illustrates a flow diagram of a method of fabricating a transistor device according to an embodiment.

### DETAILED DESCRIPTION

In the following detailed description, reference is made to the accompanying drawings, which form a part hereof, and in which is shown by way of illustration specific embodiments in which the invention may be practiced. In this regard, directional terminology, such as “top”, “bottom”, “front”, “back”, “leading”, “trailing”, etc., is used with reference to the orientation of the figure(s) being described. Because components of the embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, thereof, is not to be taken in a limiting sense, and the scope of the present invention is defined by the appended claims.

A number of exemplary embodiments will be explained below. In this case, identical structural features are identified by identical or similar reference symbols in the figures. In the context of the present description, “lateral” or “lateral direction” should be understood to mean a direction or extent that runs generally parallel to the lateral extent of a semiconductor material or semiconductor carrier. The lateral direction thus extends generally parallel to these surfaces or sides. In contrast thereto, the term “vertical” or “vertical direction” is understood to mean a direction that runs generally perpendicular to these surfaces or sides and thus to the lateral direction. The vertical direction therefore runs in the thickness direction of the semiconductor material or semiconductor carrier.

As employed in this specification, when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present.

As employed in this specification, when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

As used herein, various device types and/or doped semiconductor regions may be identified as being of n type or p type, but this is merely for convenience of description and not intended to be limiting, and such identification may be replaced by the more general description of being of a “first conductivity type” or a “second, opposite conductivity type” where the first type may be either n or p type and the second type then is either p or n type.

The figures illustrate relative doping concentrations by indicating “−” or “+” next to the doping type “n” or “p”. For example, “n⁻” means a doping concentration which is lower than the doping concentration of an “n”-doping region while an “n⁺”-doping region has a higher doping concentration than an “n”-doping region. Doping regions of the same relative doping concentration do not necessarily have the same absolute doping concentration. For example, two different “n”-doping regions may have the same or different absolute doping concentrations.

According to the present disclosure, a transistor device with a reduced gate resistance may be provided which may avoid the use of a gate electrode formed entirely of a metal such as tungsten and consequently may avoid the possible drawbacks of metal gates like introducing stress in the silicon substrate which may increase the on-state resistance (Rdson) and introducing additional parasitic capacitance between gate and source.

In a metal gate, the gate electrode in the gate trench is formed of only of a metal and the metal is in contact with the gate insulator. In a hybrid gate, two different materials are present in the gate trench to form the gate electrode. The gate of the present disclosure can be described as a partial hybrid gate as according to the present disclosure, two materials, e.g. a metal contact and a polysilicon gate electrode which is in contact with the gate insulator, are located only in the contact regions of the gate trench and outside of the contact regions the gate electrode is formed of polysilicon only which is in contact with the gate insulator.

In some embodiments, the transistor device is a MOSFET (Metal Oxide Semiconductor Field Effect Transistor) device, such as a power MOSFET, for example a vertical power MOSFET having a drift path that is perpendicular to the major surfaces. In some embodiments, the transistor device is an insulated gate bipolar transistor (IGBT) device or a Bipolar Junction Transistor (BJT).

The electrodes or terminals of the transistor device are referred to herein as source, drain and gate. As used herein, these terms also encompass the functionally equivalent terminals of other types of transistor devices, such as an insulated gate bipolar transistor (IGBT). For example, as used herein, the term “source” encompasses not only a source of a MOSFET device and of a superjunction device but also an emitter of an insulated gate bipolar transistor (IGBT) device and an emitter of a Bipolar Junction Transistor (BJT) device, the term “drain” encompasses not only a drain of a MOSFET device or of a superjunction device but also a collector of an IGBT device and a collector of a BJT device, and the term “gate” encompasses not only a gate of a MOSFET device or of a superjunction device but also a gate of an IGBT device and a base of a BJT device.

According to embodiments, the present disclosure proposes to reduce the gate resistance of a transistor device, such as a power MOSFET, through the use of electrically conductive stripes, e.g. tungsten stripes, running above the interlayer dielectric (ILD) in parallel to the gate trenches in which the gate electrode is positioned. The gate electrode itself may be formed of polysilicon. The trench in which the gate electrode is arranged may have an elongate stripe-like form having a length (its longest dimension) which extends parallel to the first major surface. The length may be measured along a first lateral direction of the semiconductor substrate The length of the trench may be greater than its depth from the first major surface, which may be in turn greater than a width of the trench. The width may be measured along a second lateral direction of the semiconductor substrate (e.g. in a direction that lies parallel to the first major surface and orthogonal to the direction in which the length of the trench is taken). The electrically conductive stripes may be contacted to the gate polysilicon in the corresponding trenches only at specific points of the chip layout, i.e. only at one or more specific points along the length of the gate trench. A plurality of contacts may be used which are spaced at intervals along the length of the trench and at intervals along the length of the gate electrode. The electrically conductive stripes that are connected to the gate electrode are located at least partially underneath the power source metal that is electrically connected to the source regions of the power MOSFET and are electrically isolated from the overlying power source metal by a further interlayer dielectric. One or more of the contacts between the gate electrode and the overlying electrically conductive stripe is located underneath the power source metal.

The number of contacts per trench in combination with the length of each contact may be referred to as the duty cycle of the contacts or the collective length of the contact and defines the trade-off between gate resistance, parasitic gate-to-source capacitance and Rdson increase caused by the stress. The contact duty cycle is less than the length of the trench. For example, the collective length of the contacts may be between 10% and 90% or between 10% and 60% of the length of the trench and/or between 10% and 90% or between 10% and 60% of the length of the gate electrode. In other words, the duty cycle/collective length may indicate the ration of a gate electrode in a given trench that is contacted to the overlying conductive stripe via the contacts. The fabrication of the electrically conductive stripes can be integrated into back-end of line (BEOL) process and only one extra (tungsten) lithography may be required. The structures described herein may provide a gate resistance reduction with less penalty, such as a lower increase in parasitic capacitance and stress-induced Rdson. Furthermore, there may also be layout flexibility, since the trade-off between gate resistance, parasitic capacitance and stress-induced Rdson penalty can be controlled by the duty cycle of the gate contacts (i.e. the selection of the number of contacts per trench and the length of each contact). A reduced gate resistance may improve the efficiency of the transistor device.

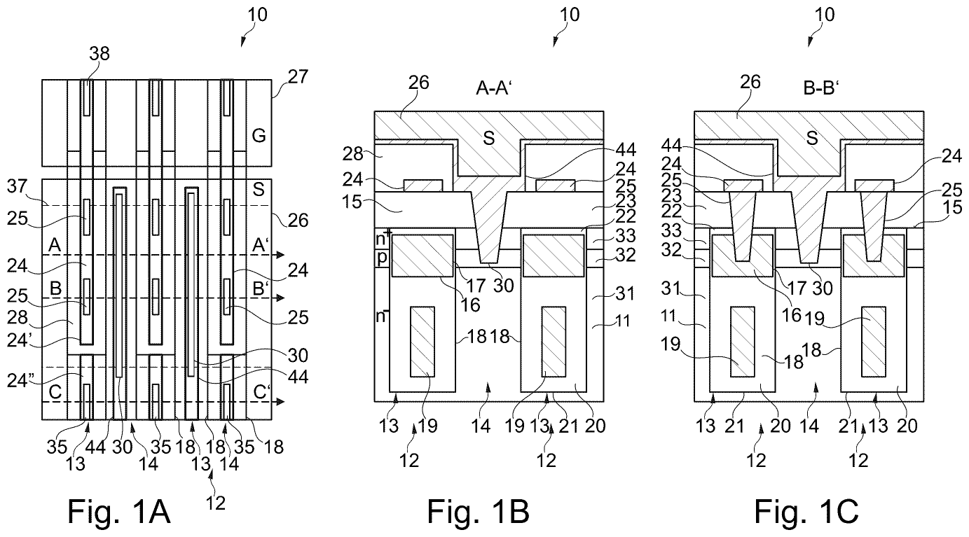

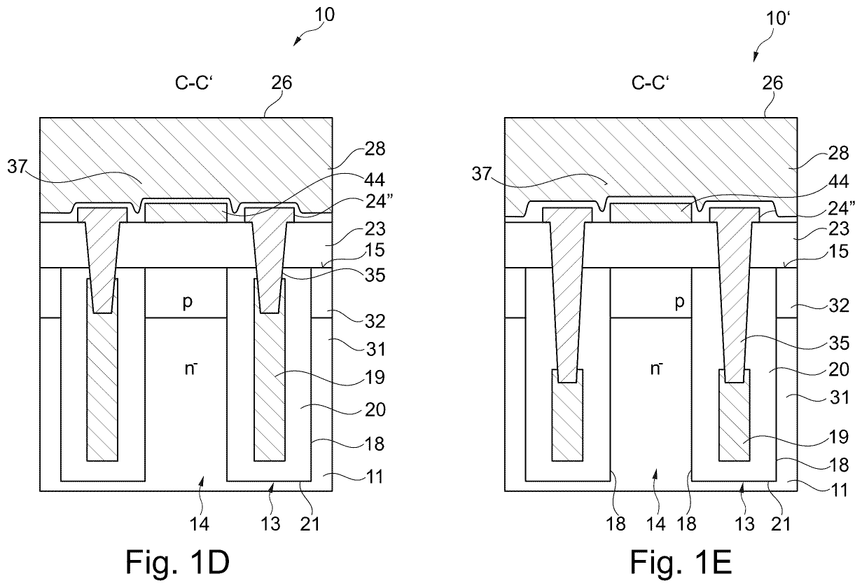

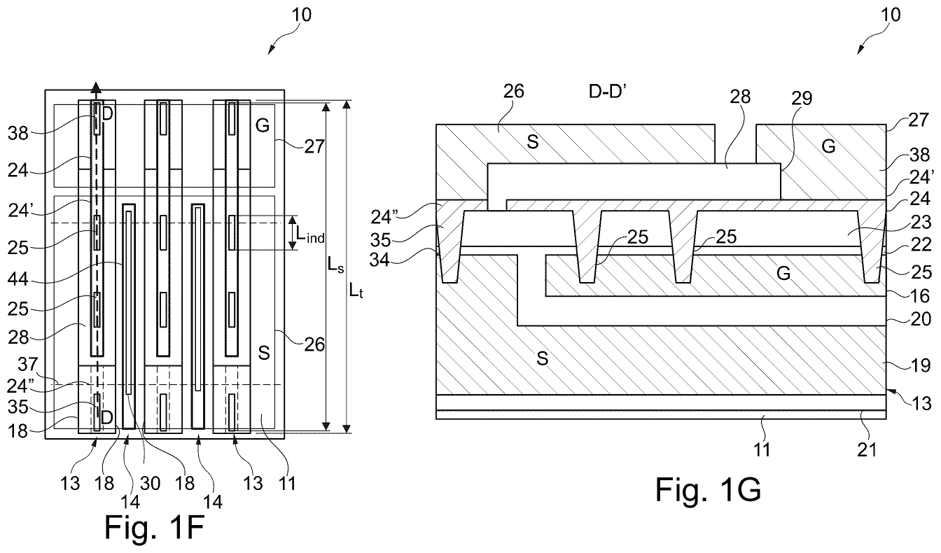

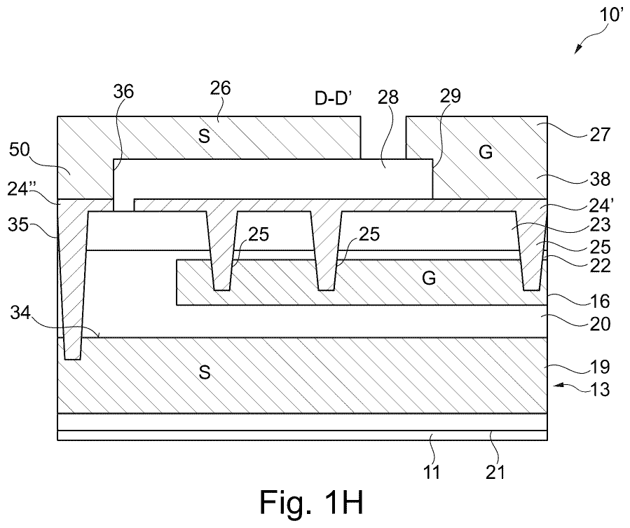

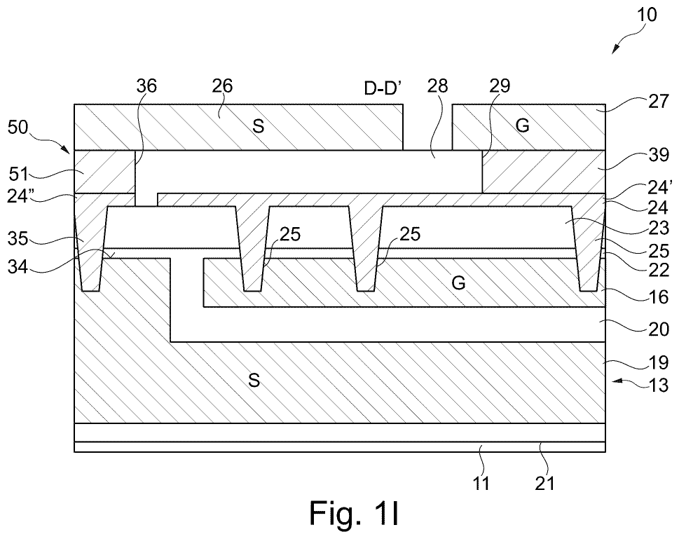

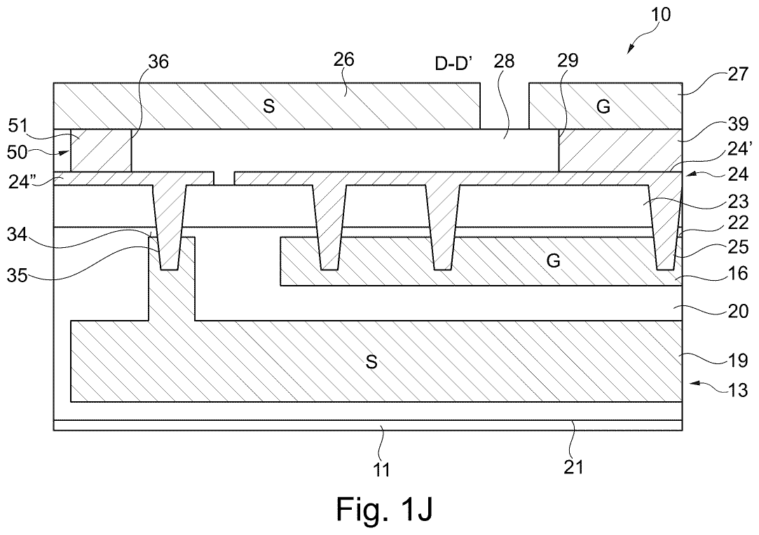

FIGS. 1A to 1H illustrate various views of a transistor device 10 according to various embodiments.

FIG. 1A illustrates a top view of the transistor device 10, FIG. 1B a cross-sectional view along the line A-A′ shown in FIG. 1A, FIG. 1C a cross-sectional view along the line B-B′, FIG. 1D cross-sectional view along line C-C′ according to one embodiment. FIG. 1E illustrates a cross-sectional view along the line C-C′ for a transistor device 10′ according to an alternative embodiment. FIG. 1F illustrates a top view of the transistor device 10 showing the line D-D′ and FIG. 1G illustrates a cross-sectional view along the line D-D′ of the transistor device 10 illustrated in FIG. 1D. FIG. 1H illustrates a cross-sectional view along the line D-D′ for the transistor device 10′ of the alternative embodiment of FIG. 1E.

The transistor device 10 comprises a semiconductor substrate 11 comprising at least one transistor cell 12. Commonly, the transistor device 10 comprises a plurality of transistor cells 12 which are electrically coupled in parallel to provide a single transistor device, e.g. a switch. The semiconductor substrate 11 may comprise silicon, for example a silicon single crystal wafer or a monocrystalline silicon epitaxial layer formed on a base substrate. Each transistor cell 12 comprises an elongate trench 13 and an elongate mesa 14. The elongate trench 13 is arranged in a first major surface 15 of the semiconductor substrate 11. The elongate trenches 13 each have a strip-like form having a length, which extends parallel to the first major surface 15. The length of the trench 13 is greater than its depth in a direction perpendicular to the first major surface 15 and the depth is greater than its width. The elongate trenches 13 extend parallel to one another such that an elongate mesa 14 is formed by the portion of the semiconductor substrate 11 positioned between two neighbouring elongate trenches 13. i.e. extending between facing side walls 18 of two neighbouring trenches 13. An elongate gate electrode 16 is formed in the elongate strip-like trench 13 and is electrically separated from the semiconductor substrate 11 by a gate dielectric 17 which is located on the sidewalls 18 of the trench 13.

In some embodiments, such as that illustrated in FIGS. 1A to 1J, the trench 13 further comprises an electrically conductive field plate 19 which is positioned towards the lower portion of the trench 13 underneath the gate electrode 16. The field plate 19 may be electrically insulated from the semiconductor substrate 11 and from the gate electrode 16, which is positioned towards the top of the trench 13, by a field plate dielectric 20 which lines the base 21 and sidewalls 18 of the trench 13 and the region between the field plate 19 and the gate electrode 16. The field plate 19 is also elongate and strip-like. The gate electrode 16 and the field pale 19 may be formed of polysilicon and are electrically conductive. The gate electrode 16 may be covered by dielectric material 22 which fills the top of the trench 13 and which is substantially coplanar with the first major surface 15 of the semiconductor substrate 11. The gate dielectric 17, the field plate dielectric 20 and the dielectrically material 22 may be formed of silicon oxide, for example.

A first electrically insulating layer 23, which may be an oxide such as silicon oxide, is arranged on the first major surface 15 and covers the trench 13 and also the mesa 14. In some embodiments, the first insulating layer 23 comprises two or more sublayers, for example silicon nitride and silicon oxide. An elongate contact connection strip 24 is arranged on the first insulating layer 23 and extends above and parallel to the elongate trench 13. The elongate contact connection strip 24 is electrically conductive and has a strip like structure and is positioned vertically above the gate electrode 16 and has a length which is greater than its width and its height. The contact connection strip 24 can be considered to be vertically aligned with the elongate trench 13. In some embodiments, the contact connection strip 24 has a width which is less than the width of the gate electrode 16 and the trench 13. The elongate contact connection strip 24 is electrically connected to the elongate gate electrode 16 in the elongate trench 13 by at least one gate contact 25 that extends through the first insulating layer 23. The gate contact 25 can be seen in the cross-sectional view illustrated in FIG. 1C which shows the plane along line B-B′ shown in FIG. 1A. The gate contact 25 extends between the contact connection strip 24 and the gate electrode 16 and through the first insulating layer 23 arranged on the first major surface 15. The gate contact 25 may also extend through the dielectric 22 arranged on the upper surface of the gate electrode 16. In some embodiments, the base of the gate contact 25 may be positioned within the height and within the material of the gate electrode 16.

A plurality of gate contacts 25 is typically provided for each trench and for each gate electrode 16. As can be seen in the top view of FIG. 1A, and also in a comparison of the cross-sectional views along the line A-A′ of FIG. 1B and the line B-B′ of FIG. 1C, in embodiments in which a plurality of gate contacts 25 is provided, the individual gate contacts 25 are spaced apart from one another at intervals along the length of the trench 13. Each of the gate contacts 25 may be elongate, e.g. its length in the direction of the length of the trench 13 is greater than its width in the direction of the width of the trench 13. The plurality of gate contacts 25 for each trench 23 and for the gate electrode 16 arranged in that trench are electrically connected to one another by the electrically conductive contact connection strip 24 that is located above that trench 13 and on the first electrically insulating layer 23.

A second electrically insulating layer 28 may be positioned on the first insulating layer 23 and may cover the contact connection strip 24. The second electrically insulating layer may be formed of an oxide, e.g. silicon oxide. Alternatively, the second electrically insulating layer may comprise two or more sublayers, for example silicon nitride and silicon oxide. A source metal layer 26 and a gate metal layer 27 may be positioned on the first major surface 15 and on the second electrically insulating layer 28. The gate metal layer 27 may be laterally spaced apart from the source metal layer 26. The source metal layer 26 may extend over the contact connection strip 24 and may be electrically insulated from the contact connection strip 24 by the second electrically insulating layer 28 which may be positioned on the first electrically insulating layer 23 and may cover the elongate contact connection strip 24.

As can be seen in the top view of FIG. 1A and the cross-sectional view along the line B-B of FIG. 1C, one or more of the gate contacts 25 are located underneath the source metal layer 26 and are electrically insulated from the overlying source metal layer 26 by the second electrically insulating layer 28. The plurality of gate contacts 25 are electrically connected to one another by the contact connection strip 24. The contact connection strip 24 may extend under the source metal layer 26 and also may extend under the gate metal layer 27.

As can be seen in the cross-sectional view along the line D-D′ along the length of the trench 13 (such as along the first lateral direction) shown in FIGS. 1F and 1G, the gate metal contacts 25 may be electrically connected to the gate metal layer 27 by way of the contact connection strip 24. The second electrically insulating layer 28 may comprise a first opening 29 which exposes a portion of the contact connection strip 24 at a location laterally adjacent to the source metal layer 26 and underneath the gate metal layer 27. In this embodiment, the gate metal layer 27 may extend through the first opening 29 and may form an electrical contact 38 to the contact connection strip 24. Alternatively, as illustrated in FIG. 1I, a separate contact 39 may be formed in the first opening 29 and a planar gate metal layer 27 may be formed which extends onto the contact 39 in the first opening 29 and on the second electrically insulating layer 28. The contact 39 may be formed from the same material as the planar gate metal layer 27, for example tungsten or aluminium.

Each of the gate contacts 25 may have a length L_{ind}, (such as its longest direction) which may extend in the longest direction of the trench 13. Since each of the gate contacts 25 may have an individual length L_{ind}, the gate contacts 25 together may have a collective length L_{c} which is the sum of the individual lengths L_{ind}. For example, for n gate contacts 25, each having an individual length, L_{ind}, where n is a natural number, L_{c}=n L_{ind}. In FIG. 1F, three gate contacts 25 are shown so that L_{c}=3 L_{ind}. If a single gate contact 25 is used, then L_{c}=L_{ind}. The gate trench 13 has a length Lₜ. The number of gate contacts 25 and the length of the individual gate contacts 25, L_{ind}, can be selected such that the collective length Lo has a value which is between 10% and 90% of the total length Lₜ of the trench 13, i.e. 0.1 Lₜ≤L_{c}≤0.9 Lₜ. This value is also referred to as duty cycle further above. In some embodiments, 0.1 Lₜ≤L_{c}≤0.6 Lₜ.

In some embodiments, the contact connection strip 24 has a length Lₛ and the length of the contact connection strip 24 is at least 70% of the length It of the trench 13, i.e. Lₛ≥0.7 Lₜ. In some embodiments, 0.7 lₜ≤Lₛ≤Lₜ.

Referring to FIGS. 1A to 1C, the source metal layer 26 may be electrically connected to the mesa 14 by a mesa contact 30 which may extend from the source metal layer 26 through the first and second insulating layers 23, 28 and into the upper portion of the mesa 14.

The mesa 14 may include a drift region 31 of a first conductivity type, e.g. n-type, a body region 32 arranged on the drift region 31, the body region 32 comprising a second conductivity type that opposes the first conductivity type, e.g., p-type if the first conductivity type is n-type, and a source region 33 which may be arranged on or in the body region 32 and which may comprise the first conductivity type. A drain region comprising the first conductivity type may be formed at the second major surface of the semiconductor substrate 11, which may oppose the first major surface 15 and which is not illustrated in drawings. The mesa contact 30 typically extends through the source region 33 and is in contact with the body region 32. As can be seen in the top view of FIG. 1A, the mesa contact 30 may be elongate and may have a longer length than the individual gate contacts 25. The transistor device 10 may be a MOSFET device, such as a power MOSFET with a vertical drift path that is often referred to as a vertical MOSFET as the drift path typically extends perpendicularly to the first major surface 15 of the substrate 11.

The lateral extent of the source region 33 may correspond to the lateral extent of the active area of the transistor device 10 and is indicated on the top view of FIG. 1A by the dashed line 37. At least one, and in some embodiments all of the contacts 25 to the gate electrode 16 in the trench 13 may be located within the boundary of the active area 37 and underneath the source metal layer 26. The contacts 30 to the mesa 15 may be located in the active area 37 and underneath the source metal layer 26. In some embodiments, a portion of the contact 30 is located outside the active area 37 in a region of the semiconductor substrate 11 which comprises a body region but no source region. This arrangement may be used to suppress parasitic bipolar.

FIG. 1D illustrates a cross-sectional view along the line C-C′ shown in FIG. 1A. FIG. 1D illustrates a portion of the transistor device 10 outside of the active area 37 of the transistor device 10. The contact 35 to the field plate 19 that is located in the lower portion of the trenches 13 may be positioned in this portion of the transistor device 10. In at least one portion of the trench 13 that is positioned outside of the active area 37, the trench 13 may be without a gate electrode 16. The length of the gate electrode 16 may, therefore, be less than the length of the trench 13. The electrical contact 35 to the field plate 19 positioned on the lower portion of the trench 13 may be positioned in sections of the length of the trench 13 which are unoccupied by the gate electrode 16.

FIG. 1G illustrates a cross-sectional view along the length of trench 13 along the line D-D′ shown in the top view of FIG. 1F. Referring to FIGS. 1D and 1G, in the section of the trench 13 which is devoid of the gate electrode, the field plate 19 may have an extension such that the extension extends almost to the first major surface 15. The field plate 19 may have an upper surface 34 which is substantially coplanar with the upper surface of the gate electrode 17 in this section of the trench 13. The extension may be formed of the same material as the field plate 19, for example polysilicon.

In one embodiment, the elongate contact connection strip 24 is divided into two separate sections 24′, 24″ and spaced apart by a gap. The first section 24′ may be positioned in the active area 37 of the transistor device 10 and may provide the contact connection strip 24 which is electrically connected to the gate contacts 25. The second section 24″, which is laterally spaced apart from the first section 24′, may be positioned outside the active area 37 of the transistor device 10. A portion of the first section 24′ and the second section 24″ may be positioned outside of the active area 37.

The first section 24′ may provide the contact connection layer 24′ and may be electrically connected by the plurality of gate contacts 25 to the gate electrode 16. The second section 24″ may be positioned above the extension of the field plate 19 and may be electrically connected to the field plate 19 by a field plate contact 35 which extends between the field plate 19 and the second section 24″. The second section 24″ may be positioned above and may overlap the trench 13 and is aligned in the long direction of the trench 13 with the first section 24′. The field plate contact 35 may be formed of a metal, for example tungsten.

The second section 24″ is electrically connected to the source metal layer 26 by a contact 50 that extends through a third opening 36 in the second insulating layer 28. The contact 50 extends between the second section 24″ and the source metal layer 26. In some embodiments, such as that illustrated in FIG. 1H, the contact 50 is integral with the source metal layer 26. In other embodiments, the contact 50 is a separate contact and the source metal layer 26 is located on this separate contact.

In some embodiments, such as that illustrated in FIG. 1J, the field plate contact 35 may be located at a lateral position which is underneath the source metal layer 26 but which is separated from the overlying source metal layer 26 by the second electrically insulating layer 28. The field plate contact 35 is electrically connected to the source metal layer 26 by the contact 50 which is located in a different portion of the trench 13 and which extends through the second insulating layer 28 and between the second section 24″ of the contact connection layer 24 and the overlying source metal layer 26. In this embodiment, the contact 50 is a separate contact 51 and the source metal layer 26 is arranged on the contact 51. The second section 24″ may form a part of a redistribution structure between the field plate 19 and the source metal layer 26 as can be seen in the cross-sectional view along the line D-D′ as illustrated in FIGS. 1G and 1J, for example.

In some embodiments, the field plate 19 may extend towards the upper portion of the trench 13, as can be seen in the cross-sectional views of FIGS. 1D and 1G for the transistor device 10.

FIGS. 1E and 1H illustrate an alternative embodiment of the transistor device 10′, in which the height of the field plate 19 is substantially uniform throughout the length of the trench 13 (e.g., also in the regions of the trench 13 which are unoccupied by the gate electrode 16). In this embodiment, the field plate contact 35 may have a larger depth and may extend from the upper surface of the first insulating layer 23, through the insulating material 18 located in the trench to the field plate 19 located towards the lower portion of the trench 13. The other features of the transistor device 10′ correspond to those described for the transistor device 10.

As can be seen in the cross-sectional views along the length of the trench 13 of the transistor devices 10, 10′, which are shown in FIGS. 1G and 1H respectively, the second insulating layer 28 may include a second opening 36 which is located above the second section 24″ of the contact connection strip which may expose the second section 24″. The source metal layer 26 may extend into the second opening 36 and may be in contact with the second section 24″ so as to electrically connect the field plate 19 located in the bottom of the trench 13 to the source metal layer 26 by way of the field plate contact 35 and the second section 24″.

The field plate contact 35 may have an elongate structure. In some embodiments, more than one field plate contact 35 may be provided for each trench 13. In some embodiments, two or more field plate contacts 35 may be provided which are located at different regions along the length of the trench 13. At each of the regions of the trench 13 in which a field plate contact 35 is located, the gate contact 16 is omitted. In these embodiments, two or more separate sections of the source metal layer 26 may be provided.

In some embodiments, the gate electrode 16 and the field plate 19 are formed of polysilicon. The gate contact 24, the mesa contact 30, the field plate contact 35 and the contact connection strip 24, and the separate sections 24′, 24″ if present, may be formed of tungsten. The source metal layer 26 may comprise aluminium, for example an aluminium copper alloy. In some embodiments, the source metal layer 26 comprises two or more sublayers, for example, a first sublayer formed by tungsten and a second sublayer formed of aluminium copper alloy formed on the first sublayer. The gate metal layer 27 may comprise aluminium, for example an aluminium copper alloy. In some embodiments, the gate metal layer 27 comprises two or more sublayers, for example a first sublayer formed by tungsten and a second sublayer formed of aluminium copper alloy formed on the first sublayer.

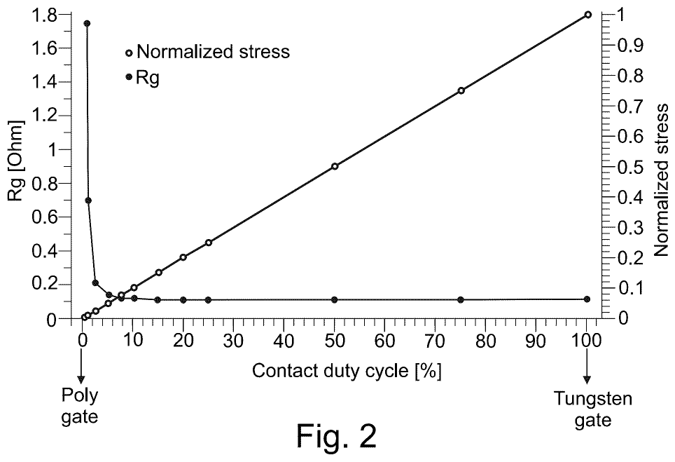

FIG. 2 illustrates a graph of gate resistance and normalised stress simulated for transistor devices comprising differing gate contact duty cycles. The duty cycle refers to the number of individual gate contacts and the length of each of the individual gate contacts which gives a collective length of the gate contact with respect to the total length of the gate electrode.

FIG. 2 shows that for the simulated conditions there is a trade-off between gate resistance Rg and normalized stress. As the gate contact collective length increases from 0% to 100%, the normalised stress increases monotonically from 0 to 1. As the gate contact collective length increases from 0%, the gate resistance Rg decreases rapidly from around 1.75 Ohms for a collective contact length of 1% to a value of slightly greater than 0.1 Ohms for a collective contact length of up to around 5%. For increased duty cycles up to 100%, the gate resistance Rg is substantially constant around 0.1 Ohms or decreases slightly. A duty cycle of 0% corresponds to a device having a polysilicon gate electrode. In practice, a device having a polysilicon gate electrode includes a contact to the polysilicon gate electrode which is often formed of a metal. Therefore, for a practical device, the duty cycle is slightly greater than 0%, for example 0.1% or 0.5%, for a device comprising a polysilicon gate. A duty cycle of 100% corresponds to a device having a metal gate electrode, for example a tungsten gate electrode. A tungsten gate has a low gate resistance Rg but a high normalised stress, whereas a polysilicon gate electrode has a low normalised stress but higher gate resistance.

This trade-off between gate resistance Rg and normalized stress can be tuned by varying the duty cycle of the gate contacts along a particular trench, i.e. by varying the collective length of the gate contacts with respect to the length of the gate electrode within the trench. This could be done by varying the length of the gate contacts 25 and/or by varying the number of gate contacts 25.

It can be seen from FIG. 2 that for these simulation conditions a 10% duty cycle allows a reduced gate resistance with a much lower stress penalty compared to a tungsten gate (100%). In other words, the collective length of a plurality of gate contacts of around 10% of the total length of the gate electrode leads to a low gate resistance Rg and low normalized stress.

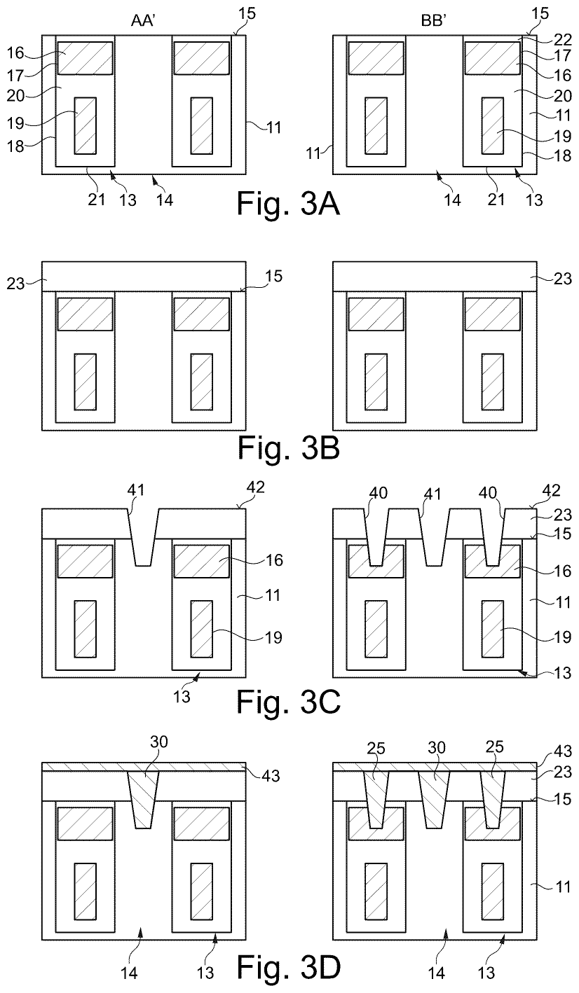

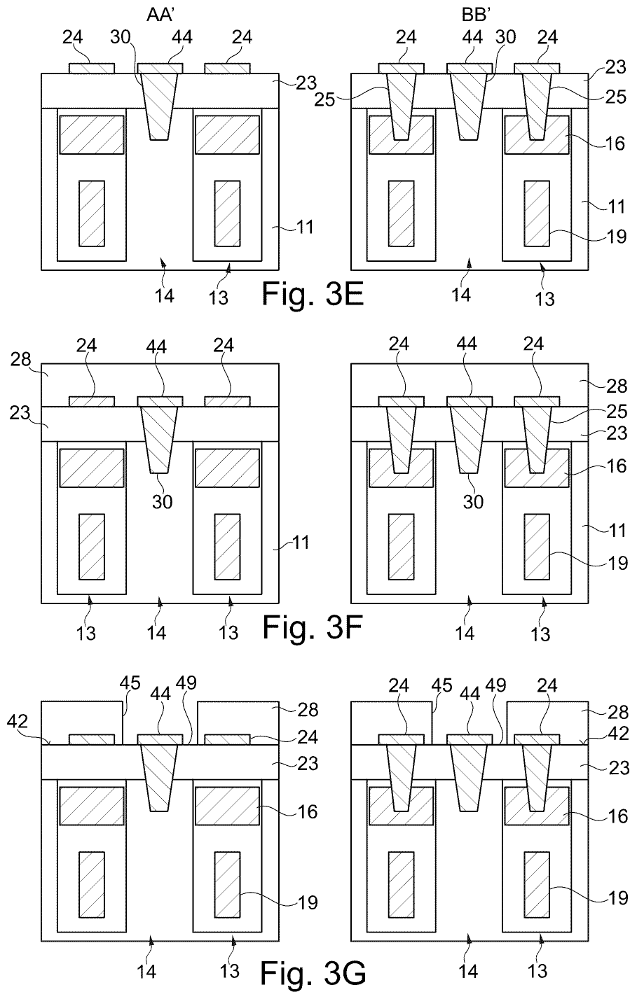

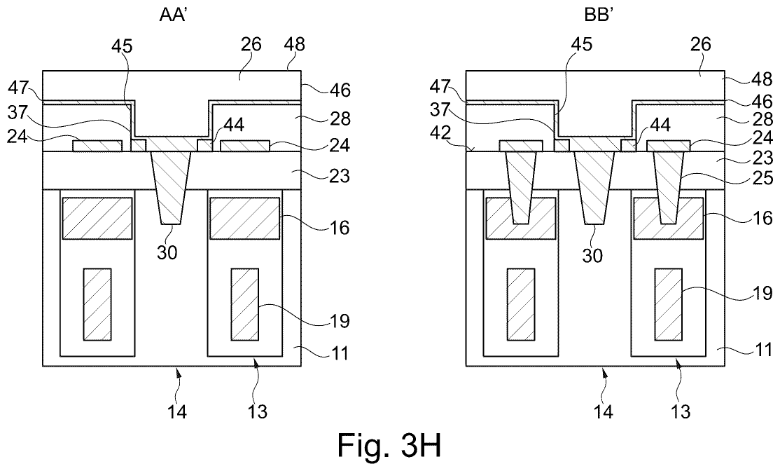

A method of fabricating a transistor device will now be described with reference to FIGS. 3A to 3H. The method may be used for fabricating the transistor devices 10, 10′ illustrated in FIGS. 1A to 1J. Each of FIGS. 3A to 3H illustrates a cross-sectional view at two positions along the length of the trench 13 corresponding to the lines A-A′ and B-B′ of FIG. 1A.

FIG. 3A illustrates cross-sectional views of the semiconductor substrate 11 in which the elongate strip-like trenches 13 including the field plate 19 towards the bottom of the trench 13 and the gate electrode 16 towards the top of the trench 13 have been fabricated. The field plate 19 is electrically separated from the semiconductor substrate 11 by at least one electrically insulating layer 20 which may cover the base 21 and sidewalls 18 of the trench 13 and the space between the field plate 19 and the gate electrode 16. The gate electrode 16 is separated from the sidewalls 18 of the trench 13 by a gate insulating layer 17 and may be capped or covered at the top by the electrically insulating layer 22. The upper surface of the insulating layer 22 may be coplanar with the first major surface 15 of the substrate 11. The body region 32 and source region 33 may be formed in the elongate strip-like mesas 14 that are formed by the portions of the semiconductor substrate 11 between the side walls of neighbouring ones of the trenches 13. The semiconductor substrate 11 may be formed of silicon and the transistor device, which is to be formed in the substrate 11, may be a MOSFET device with a vertical drift path.

Referring to FIG. 3B, a first insulating layer 23 may be formed on the first major surface 15 of the semiconductor substrate 11 and may cover the elongate strip-like mesas 14 and the elongate trenches 13. Referring to FIG. 3C, a first opening 40 may be formed at a predetermined position of the length of the trench 13. The first opening 40 may extend through the first insulating layer 23 and into the trench 13 and may have a base formed by or within the material of the gate electrode 16, which may, e.g., be made of polysilicon. Typically, two or more openings 40 are formed which are spaced apart at intervals along the length of the trench 13. The length of the trench 13 is its longest direction which extends into the plane of the drawing. The spacing of the first openings 40, each of which may have a length which is less than the length of the trench 13, can be seen in FIG. 3C in that the opening 40 can be seen in the cross-sectional view along the line B-B′ but not in the cross-sectional view along the line A-A′. A second opening 41 may be formed which is positioned above the mesa 14 and which may extend along the majority of the length of the mesa 14. The second opening 41 can be seen in the cross-sectional view along the line B-B′ and in the cross-sectional view along the line A-A′ and may have a greater length than the first opening 40. The first and second openings 40, 41 may be formed in the same process, for example by suitable structuring of a mask formed on the first insulating layer 23 and etching of the exposed portions of the first insulating layer 23, the insulating layer 22 and possibility the gate electrode 16 in the trench 13 and of the first insulating layer 23 and semiconductor material of the mesa 14, respectively.

Referring to FIG. 3D, an electrically conductive layer 43, for example formed of tungsten, is formed on the upper surface 42 of the first insulating layer 23 which may fill the first and second openings 40, 41 thus forming one or more contacts 25 to the gate electrode 16 in each trench 13 and a contact 30 to the mesa 14, respectively. The electrically conductive layer 43 may also extend over the upper surface 42 of the first insulating layer 23.

Referring to FIG. 3E, the electrically conductive layer 43 is structured so as to form an electrically conductive strip 24 positioned above each of the trenches 13. The individual strips 24 may each have a width which is greater than the width of the first opening 40 and therefore greater than the width of the individual ones of the gate contacts 25. One individual strip 24 may be in contact with multiple and/or all of the gate contacts 25 formed to the gate electrode 16 within that trench 13 and may form a gate contact connection strip 24 which is positioned in a plane above the gate electrode 16.

The conductive layer 43 may also be structured to provide an elongate strip 44 which is positioned above the mesa 14 and which is in contact with the mesa contact 30. The conductive layer 43 may therefore be structured to provide a plurality of separate strip-like structures 24, 44 which are positioned on the upper surface 42 of the first insulating layer 23 and spaced apart from one another, e.g., such that the strips 24, 44 are alternately positioned on the first insulating layer 23. In some positions along the length of the trench 13, as illustrated in the cross-sectional view along the line A-A′ in FIG. 3E, the strip 24 is vertically spaced apart and electrically insulated from the gate electrode 16 at that position by the electrically insulating layer 22 arranged on the top of the trench 13 and by the first insulating layer 23. In other positions, such as that illustrated in along cross-sectional view along the line B-B′ shown in FIG. 3E, the connection strip 24 is arranged directly on the gate contacts 25 such that the connection strip 24 is electrically connected at intervals to the elongate gate electrode 16.

Referring to FIG. 3F, a second electrically insulating layer 28 is formed which covers the strips 24, 44 and the first electrically insulating layer 23. Referring to FIG. 3G, a third opening 45 is formed in the second electrically insulating layer 28. The third opening 45 is positioned above the mesa 14 and may expose the strip 44 arranged on the first insulating layer 23 above the mesa 14. The third opening 45 may have a width such that contiguous regions of the second electrically insulating layer 28 are exposed. The third opening 45 may have a length which corresponds to the length of the elongate mesa 14.

Referring to FIG. 3H, an electrically conductive material 26 may then be formed in the third opening 45 which may also extend over the upper surface 46 of the second electrically insulating layer 28. The electrically conductive material 26 may be electrically connected to the mesa 14 (such as to one or more of the source region 33 and the body region 32) and may provide a source metallization layer. The source metallization layer 26 may extend over and may be electrically insulated from the gate contact connection strip 24 by the intervening second insulating layer 28.

In some embodiments, such as that illustrated in FIG. 3H, the source metallic layer 26 comprises two or more sublayers. A first sublayer 47 is deposited over the upper surface 46 and sidewalls 47 of the opening 45 and over the exposed portions 49 of the upper surface 42 of the first electrically insulating layer 23 and on the electrically conductive strip 44. The first sublayer 47 may be formed of tungsten, for example. A second sublayer 48 is then deposited which fills the remainder of the third opening 45 which extends over the first sublayer 47. The second sublayer 48 may comprise aluminium and/or copper or may comprise aluminium copper alloy. Thus, the electrically conductive layer 26 is electrically connected to the mesa 14 by way of the mesa contact 30 formed in the second opening 41.

As an alternative to the process discussed above with reference to FIGS. 3A to 3H, a dual damascene process may be used to realize the electrically conductive strip 24 above the trench 13 in which the polysilicon gate 16 is formed, and the contacts 25 to the polysilicon gate electrode 16. In other words, the contacts 25 and strip 24 are formed in one deposition process and are integral. Similarly, the contact 30 and strip 44 of the mesa may be formed using the same dual damascene process and be integral.

In this alternative process, a first lithography mask and etch step defines the position of the first contact holes 40. The first contact holes are initially etched down to a given depth into the dielectric material 23, but do not reach the polysilicon gate electrode 16. A second lithography mask and etch step is used to structure elongate openings for the strips 24 within the dielectric material 23. In this second etch step, the first contact holes 40 are further etched down, i.e. their depth is extended to the gate electrode 16. A TiSi sublayer is formed on the polysilicon gate electrode and the contact holes 40 and elongate openings are filled with tungsten to form the gate contacts 25 and strip 24, respectively. Optionally, a CMP step can be used to remove the tungsten from the wafer surface. This alternative process sequence can be advantageous if processing in combination with the other metallization layers of the device is desirable.

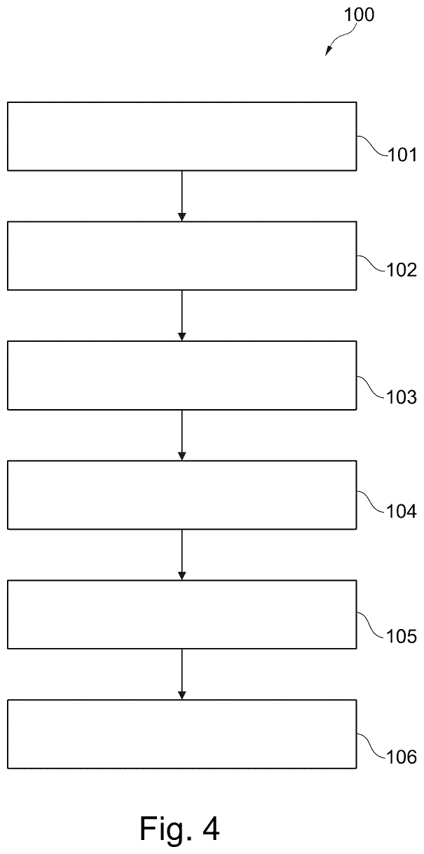

FIG. 4 illustrates a flow diagram 100 of a method for fabricating a transistor device. In box 101, a first insulating layer is formed on a first major surface of a semiconductor substrate comprising at least one transistor cell, the transistor cell comprising an elongate trench and an elongate mesa. The elongate trench is arranged in the first major surface of the semiconductor substrate and comprises an elongate gate electrode that is electrically separated from the semiconductor substrate by a gate dielectric. The first insulating layer covers the elongate trench.

In box 102, at least one first contact is formed in the first insulating layer. The at least one first contact is connected to the elongate gate electrode in the elongate trench.

In box 103, a contact connection strip is formed on the first insulating layer and on the at least one first contact. The contact connection strip is located vertically above and extends parallel to the gate trench so that the contact connection strip is vertically aligned with the gate trench.

In box 105, a second insulating layer is formed on the contact connection strip.

In box 106, a source metal layer is formed on the second insulating layer. In box 107, the source metal layer is electrically connected to the mesa. The source metal layer extends over and is electrically insulated from the contact connection strip by the second insulating layer. The source metal layer may be electrically connected to the mesa by forming a mesa contact in the first insulating layer, for example at the same time as forming the at least one contact that is connected to the elongate gate electrode positioned in the trench.

In an embodiment, a plurality of contact connection strips is connected to a common gate metallization layer, e.g. a gate pad or a gate runner or gate finger, by a contact extending from the contact connection strip to the gate metallization layer. The gate metallization layer is arranged on the first major surface of the semiconductor substrate laterally adjacent to the source metallization layer, e.g. a source pad.

To summarise, a transistor device, for example a power MOSFET with a vertical drift path, is provided that has a lower gate resistance. The gate electrode within the respective gate trenches can be formed of polysilicon and is connected to an additional gate contact connection strip that is located vertically above the trench by at least one, typically a plurally of contacts, that are located underneath the power source metallization. The cross-sectional area of the contact between the gate electrode and the metallisation structure of the device is increased due to the larger contact area between the gate electrode and the plurality of gate contacts located at intervals along the length of the trench. Additional chip area is not required for the larger contact area, since the additional contacts to the gate electrode and the electrical connection of these additional contacts to one another by the additional gate contact connection strip is located under the source power metallisation.

Although the present disclosure is not so limited, the following numbered examples demonstrate one or more aspects of the disclosure.

Example 1. A transistor device, comprising: a semiconductor substrate comprising at least one transistor cell, the transistor cell comprising an elongate trench and an elongate mesa; the elongate trench being arranged in a first major surface of the semiconductor substrate and comprising an elongate gate electrode that is electrically separated from the semiconductor substrate by a gate dielectric; a first insulating layer arranged on the first major surface and covering the elongate trench; an elongate contact connection strip arranged on the first insulating layer and extending above and parallel to the elongate trench, the elongate contact connection strip being electrically connected to the elongate gate electrode in the elongate trench by at least one first contact that extends through the first insulating layer.

Example 2. A transistor device according to example 1, further comprising a source metal layer that is electrically connected to the mesa, wherein the source metal layer extends over and is electrically insulated from the contact connection strip.

Example 3. A transistor device according to example 2, wherein the contact connection strip is located vertically under the source metal layer and is electrically insulated from the source metal layer by a second insulating layer.

Example 4. A transistor device according to example 2 or example 3, wherein at least one of the first contacts is located vertically under the source metal layer.

Example 5. A transistor device according to any one of examples 1 to 4, wherein the at least one of the first contacts extends through the first insulating layer between the gate electrode and the elongate contact connection strip.

Example 6. A transistor device according to any one of examples 1 to 5, wherein a plurality of first contacts is provided that are spaced apart along the length of the elongate trench.

Example 7. A transistor device according to any one of examples 2 to 6, wherein two or more of the first contacts are arranged under and covered by the source metal layer.

Example 8. A transistor device according to any one of examples 1 to 7, wherein the at least one first contact has a collective length L_{c} and the gate trench has a length Lₜ, wherein 0.1 Lₜ≤L_{c}≤0.9 Lₜ.

Example 9. A transistor device according to example 8, wherein 0.1 Lₜ≤L_{c}≤0.6 Lₜ.

Example 10. A transistor device according to example 8 or example 9, wherein the contact connection strip has a length Lₛ, wherein Lₛ≥0.7 Lₜ

Example 11. A transistor device according to example 10, wherein 0.7 Lₛ ≤Lₜ≤Lₛ.

Example 12. A transistor device according to any one of examples 1 to 11, further comprising: a second insulating layer that is arranged on the contact connection strip and on the first insulating layer; an elongate mesa contact; wherein the source metal layer is arranged on the second insulating layer and the elongate mesa contact extends from the source metal layer through the first and second insulating layers and into the mesa.

Example 13. A transistor device according to example 12, further comprising a gate metal layer that is arranged on the second insulating layer and laterally adjacent and spaced apart from the source metal layer, wherein the gate metal layer is electrically connected to the contact connection strip by a second contact that extends through the second insulating layer and between the gate metal layer and the contact connection strip.

Example 14. A transistor device according to example 12 or example 13, wherein the second insulating layer comprises a second opening that exposes the contact connection strip and the gate metal layer is arranged in the first opening to form the second contact.

Example 15. A transistor device according to any one of examples 1 to 14, wherein the gate trench further comprises a field plate that is arranged in a lower portion of the trench and that is electrically separated from the semiconductor substrate and from the elongate gate electrode by a field dielectric.

Example 16. A transistor device according to example 15, wherein the field plate is electrically connected to the source metal layer by a field plate contact that extends from the field plate through the first and second insulating layers to the source metal layer.

Example 17. A transistor device according to example 15 or example 16, wherein the field plate contact is located in a portion of the gate trench that is located laterally outside of the active area of the transistor device and underneath the source metal layer.

Example 18. A transistor device according to any one of examples 15 to 17, wherein the contact connection strip comprises a first section and a second section that are laterally spaced apart by the first insulating layer, wherein the first section is electrically connected to the first contacts and the second section to the field plate contact.

Example 19. A transistor device according to example 18, wherein the second section is electrically connected to the source metal layer.

Example 20. A transistor device according to example 18 or example 19, wherein the second insulating layer comprises a first opening that exposes the second section and the source metal layer is arranged in the first opening.

Example 21. A transistor device according to any one of examples 1 to 20, wherein a top surface of the gate electrode is covered by an upper portion of the gate dielectric and the first insulating layer is arranged on the upper portion of the gate dielectric.

Example 22. A transistor device according to any one of examples 1 to 21, wherein the gate electrode is formed of polysilicon, the first contact comprises tungsten and the contact connection strip comprises tungsten.

Example 23. A transistor device according to any one of examples 1 to 22, wherein the elongate mesa contact comprises tungsten and the source metal layer comprises Al.

Example 24. A transistor device according to any one of examples 1 to 23, wherein the first contact, the contact connection strip and the elongate mesa contact are formed of tungsten.

Example 25. A transistor device according to any one of examples 2 to 24, wherein the source metal layer comprises an alloy comprising Al and Cu.

Example 26. A transistor device according to any one of examples 2 to 25, wherein the source metal layer comprises a first sublayer formed by tungsten and a second sublayer formed of an AlCu alloy.

Example 27. A transistor device according to any one of examples 1 to 26, wherein the semiconductor substrate is formed of silicon.

Example 28. A transistor device according to any one of examples 1 to 27, wherein the elongate mesa comprises a drift region of a first conductivity type, a body region of a second conductivity type that opposes the first conductivity, the body region being arranged on the drift region, and a source region of the first conductivity type formed on and/or in the body region, wherein a drain region of the first conductivity type is arranged in or on a second major surface of the semiconductor substrate that opposes the first major surface.

Example 29. A transistor device according to any one of examples 1 to 28, wherein the transistor device is a MOSFET device or a vertical MOSFET device or an IGBT.

Example 30. A method comprising: forming a first insulating layer on a first major surface of a semiconductor substrate comprising at least one transistor cell, the transistor cell comprising an elongate trench and an elongate mesa, wherein the elongate trench is arranged in the first major surface of the semiconductor substrate and comprises an elongate gate electrode that is electrically separated from the semiconductor substrate by a gate dielectric, wherein the first insulating layer covers the elongate trench; forming at least one first contact in the first insulating layer that is connected to the elongate gate electrode in the elongate trench; forming a contact connection strip on the first insulating layer that is electrically connected to the at least one first contact, wherein the contact connection strip extends vertically above and parallel to the gate trench; forming a second insulating layer on the contact connection strip; forming a source metal layer on the second insulating layer; electrically connecting the source metal layer to the mesa, wherein the source metal layer extends over and is electrically insulated from the contact connection strip by the second insulating layer.

Example 31. A method according to example 30, further comprising: forming at least one first opening in the first insulating layer that exposes the gate electrode and at least one elongate second opening in the first insulating layer that extends into the mesa; forming a first metallic layer in the first and second openings and on the first insulating layer; and structuring the first metallic layer to form the elongate contact connection strip and the elongate mesa contact.

Example 32. A method according to example 31, wherein the electrically connecting the source metal layer to the mesa, the method further comprising: forming an elongate third opening in the second insulating layer above the elongate mesa contact; and forming the source metal layer in the third opening and over the second insulating layer.

Example 33. A method according to any one of examples 30 to 32, wherein the elongate mesa comprises a drift region of a first conductivity type, a body region of a second conductivity type that opposes the first conductivity, the body region being arranged on the drift region and a source region of the first conductivity type formed on and/or in the body region, wherein a drain region of the first conductivity type is arranged in or on a second major surface of the semiconductor substrate that opposes the first major surface.

Example 34. A method according to any one of examples 30 to 33, wherein the forming a contact connection strip on the first insulating layer that is electrically connected to the at least one first contact, is performed subsequently to the forming the at least one first contact and comprises forming the contact connection strip on the at least one first contact and on the first insulating layer.

Example 35. A method according to any one of examples 30 to 33, wherein a single deposition process is used to form the at least one first contact in the first insulating layer that is connected to the elongate gate electrode in the elongate trench and the contact connection strip on the first insulating layer that is electrically connected to the at least one first contact.

Spatially relative terms such as “under”, “below”, “lower”, “over”, “upper” and the like are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise. It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A transistor device, comprising:
a semiconductor substrate comprising at least one transistor cell, the at least one transistor cell comprising an elongate trench and an elongate mesa, the elongate trench being arranged in a first major surface of the semiconductor substrate and comprising an elongate gate electrode that is electrically separated from the semiconductor substrate by a gate dielectric;
a first insulating layer arranged on the first major surface and covering the elongate trench;
an elongate contact connection strip arranged on the first insulating layer and extending above and parallel to the elongate trench, the elongate contact connection strip being electrically connected to the elongate gate electrode in the elongate trench by at least one first contact that extends through the first insulating layer.

2. The transistor device of claim 1, further comprising a source metal layer electrically connected to the elongate mesa, wherein the source metal layer extends over and is electrically insulated from the elongate contact connection strip.

3. The transistor device of claim 2, wherein the at least one first contact is located vertically under the source metal layer.

4. The transistor device of claim 2, wherein the contact connection strip is located vertically under the source metal layer and is electrically insulated from the source metal layer by a second insulating layer.

5. The transistor device of claim 2, wherein two or more of the first contacts are arranged under and covered by the source metal layer.

6. The transistor device of claim 1, wherein a plurality of first contacts is provided that are spaced apart along a length of the elongate trench.

7. The transistor device of claim 1, wherein the at least one first contact has a collective length L_{c} and the elongate trench has a length Lₜ, wherein 0.1 Lₜ≤L_{c}≤0.9 Lₜ.

8. The transistor device of claim 1, further comprising:
a source metal layer electrically connected to the elongate mesa;
a second insulating layer arranged on the elongate contact connection strip and on the first insulating layer; and
an elongate mesa contact,
wherein the source metal layer is arranged on the second insulating layer and the elongate mesa contact extends from the source metal layer through the first and second insulating layers and into the mesa.

9. The transistor device of claim 8, further comprising:
a gate metal layer arranged on the second insulating layer and laterally adjacent and spaced apart from the source metal layer,
wherein the gate metal layer is electrically connected to the elongate contact connection strip by a second contact that extends through the second insulating layer and between the gate metal layer and the contact connection strip.

10. The transistor device of claim 8, wherein the second insulating layer comprises a second opening that exposes the contact connection strip and the gate metal layer is arranged in the first opening to form the second contact.

11. The transistor device of claim 1, wherein the elongate trench further comprises a field plate arranged in a lower portion of the elongate trench and electrically separated from the semiconductor substrate and from the elongate gate electrode by a field dielectric.

12. The transistor device of claim 11, wherein the field plate is electrically connected to the source metal layer by a field plate contact that extends from the field plate through the first and second insulating layers to the source metal layer.

13. The transistor device of claim 1, wherein a top surface of the elongate gate electrode is covered by an upper portion of the gate dielectric and the first insulating layer is arranged on the upper portion of the gate dielectric.

14. The transistor device of claim 1, wherein the elongate gate electrode comprises polysilicon, the first contact comprises tungsten, and the contact connection strip comprises tungsten.

15. The transistor device of claim 1, wherein the elongate mesa contact comprises tungsten and the source metal layer comprises aluminum.

16. The transistor device of claim 1, wherein the elongate mesa comprises a drift region of a first conductivity type, a body region of a second conductivity type that opposes the first conductivity, the body region being arranged on the drift region, and a source region of the first conductivity type formed on and/or in the body region, and wherein a drain region of the first conductivity type is arranged in or on a second major surface of the semiconductor substrate that opposes the first major surface.

17. The transistor device of claim 1, wherein the at least one of the first contacts extends through the first insulating layer between the elongate gate electrode and the elongate contact connection strip.

18. A method, comprising:
forming a first insulating layer on a first major surface of a semiconductor substrate that comprises at least one transistor cell, the at least one transistor cell comprising an elongate trench and an elongate mesa, wherein the elongate trench is arranged in the first major surface of the semiconductor substrate and comprises an elongate gate electrode that is electrically separated from the semiconductor substrate by a gate dielectric, wherein the first insulating layer covers the elongate trench,
forming at least one first contact in the first insulating layer that is connected to the elongate gate electrode in the elongate trench;
forming an elongate contact connection strip on the first insulating layer that is electrically connected to the at least one first contact, wherein the contact connection strip extends vertically above and parallel to the gate trench;
forming a second insulating layer on the elongate contact connection strip;
forming a source metal layer on the second insulating layer; and
electrically connecting the source metal layer to the elongate mesa,
wherein the source metal layer extends over and is electrically insulated from the contact connection strip by the second insulating layer.

19. The method of claim 18, further comprising:
forming at least one first opening in the first insulating layer that exposes the gate electrode and at least one elongate second opening in the first insulating layer that extends into the elongate mesa;
forming a first metallic layer in the first and second openings and on the first insulating layer; and
structuring the first metallic layer to form the elongate contact connection strip and the elongate mesa contact.

20. The method of claim 19, wherein the electrically connecting the source metal layer to the elongate mesa comprises:
forming an elongate third opening in the second insulating layer above the elongate mesa contact; and
forming the source metal layer in the third opening and over the second insulating layer.
